(19) United States
(12) Patent Application Publication
(10) Pub. No.: US 2012/0281333 A1
(43) Pub. Date: Nov. 8, 2012

(54) TEMPERATURE-CONTROLLABLE ELECTROSTATIC CHUCK

(75) Inventor: RICHARD F. MCRAY, Penn Valley, CA (US)

(73) Assignee: ADVANCED ION BEAM TECHNOLOGY, INC., Fremont, CA (US)

(21) Appl. No.: 13/102,945

(22) Filed: May 6, 2011

(51) Int. Cl. H01L 21/687

(52) U.S. Cl. 361/234

(57) ABSTRACT

The invention is directed to a temperature-controllable electrostatic chuck having a heat-transfer body, one or more electrodes and one or more thermopile devices. The heat-transfer body transfers heat between the interior of the electrostatic chuck and the exterior of the electrostatic chuck via a heat-transfer assembly with heat-transfer fluid circulated to and from an external chiller. The one or more thermopile devices are in series between the heat-transfer body and a top surface of the electrostatic chuck, so that heat may be further transferred between a workpiece held on the top surface and the heat-transfer body. Accordingly, because the workpiece temperature may be adjusted by both the external chiller and the thermopile devices, the workpiece temperature may be further lowered when the cold sides of the thermopile device face the workpiece. Otherwise, the workpiece temperature may be further elevated when the hot sides of the thermopile device face the workpiece.

### BACKGROUND OF THE INVENTION

1. Field of the Invention

The present invention generally relates to an electrostatic chuck and more particularly to a temperature-controllable electrostatic chuck adaptable to a super lower and/or higher temperature.

2. Description of Related Art

An ion implanter is one of the important processing tools used in fabricating modern devices, such as an integrated circuit (IC), a random access memory (RAM), a flat panel display (FPD), a solar cell, etc. Ion implantation performed by the ion implanter may change physical or chemical properties of a workpiece, such as a semiconductor wafer, a glass plate or other plate-like objects, by implanting ions of a material or materials. FIG. 1 shows a schematic diagram illustrating a basic configuration of a conventional ion implanter, which primarily includes an ion source 10, a mass analyzer 12 and an end station 14. The ion source 10 generates desired ions of material(s). The mass analyzer 12 sorts the ions by their mass-to-charge ratios such that only the ions having the required specific mass-to-charge ratio(s) may go out of the mass analyzer 12, resulting in an ion beam 16. The ion beam 16 finally impinges on a workpiece 18 disposed in the end station 14.

The profile of the ion beam 16 impinged on the workpiece 18 is sometimes non-uniform and/or irregular, even if one or more electrodes and/or magnets are positioned between the mass analyzer 12 and the end station 14 for the purpose of adjusting the ion beam 16. The non-uniformity and/or the irregularities significantly degrade the ion implantation result. Moreover, when the diameter of the workpiece 18 is large and the ion beam 16 is substantially shorter than the diameter of the workpiece 18, the workpiece 18 needs to be moved and scanned with respect to the ion beam 16 or vice versa such that the ion beam 16 may uniformly implant the entire workpiece 18. FIG. 2 shows an exemplary beam path 16A of scanning the ion beam 16 with a beam cross-section 1613 on the workpiece 18. The scanning usually involves translational motion and/or rotational motion of the workpiece 18 by one or more motors during the implantation process. In general, an electrostatic chuck (i.e., electrostatic chuck) is used to hold the workpiece 18 during the translational/rotational motion of the workpiece 18. The electrodes embedded in the electrostatic chuck apply voltage to induce a charge on the workpiece 18, so that the workpiece 18 is tightly held by the electrostatic chuck.

When the workpiece 18 is implanted with the ion beam 16, temperature of the workpiece 18 accordingly elevates as a result of kinetic energy carried by the implanted ions. Furthermore, when the device size is substantially scaled down in a modern product, such as a modern integrated circuit, thermal diffusion caused by the raised temperature will have a larger impact on the quality, for example, of an implanted profile in the fabricated device. In order to alleviate the effect caused by the thermal diffusion or to obtain better implantation control, some schemes have been proposed to implant the workpiece 18 at a sub-zero temperature. For example, the workpiece temperature may be decreased to well below 0° C. for the requirement of reducing the thermal diffusion of implanted ions, and may be decreased to as low as −100° C. for the formation of the extra shallow junctions.

These low temperatures can be attained by delivering coolant, gas or liquid, through the coolant tubes between a chiller and the electrostatic chuck for cooling down the workpiece 18. FIG. 3 schematically shows a conventional electrostatic chuck 3 capable of clamping the workpiece 18. Specifically, a chiller 31A is connected to the electrostatic chuck 3 via a heat-transfer assembly 31B, such as a combination of an inward coolant tube and an outward coolant tube, and a power supply 32A is connected to the electrostatic chuck 3 via conductors 32B. The electrostatic chuck 3 may be moved and/or rotated by a motor 33A through a shaft 33B to achieve the required translation and/or rotation of the workpiece 18. The heat-transfer assembly 31B is usually made of elastomeric material such as plastic or rubber that provides indispensable flexibility during the translation and/or rotation of the workpiece 18. However, the low temperature can be harmful to elastomeric material which becomes brittle typically in the −40 C to −60 C range. Sometimes, the heat-transfer assembly 31B is made of metal that is flexed to provide the necessary movements, especially the small movements. Similarly, the quality of the metal may be degraded when the temperature is low enough. Therefore, one associated problem is that the achievable lowest workpiece temperature is limited by the material used for the heat-transfer assembly 31B. The availability of suitable materials falls as the potential workpiece temperature decreases, particularly when the materials are subjected to translational and/or rotational stress as mentioned above.

One more problem associated with the conventional electrostatic chuck is that the available cooling rate of the workpiece is limited primarily by the achievable lowest electrostatic chuck temperature. FIG. 4 shows an exemplary response curve illustrating the relationship between workpiece temperature and elapsed time on a conventional electrostatic chuck operating at −50° C. (e.g., a conventional electrostatic chuck at a fixed temperature −50° C.). In the example, the workpiece 18 is moved from an atmosphere environment at room temperature into an evacuated chamber and then cooled by a conventional electrostatic chuck at fixed temperature −50° C. As customary, an interface Nitrogen gas with a pressure 10 Torr is present in this example at the wafer to electrostatic chuck interface as a thermal transfer medium. As shown in the exemplary response curve, the workpiece temperature takes about 28 seconds to get down from 20° C. to −40° C. Significantly, a slow cooling rate definitely hinders the throughput of any processing tool using the conventional electrostatic chuck.

For the aforementioned disadvantages associated with the conventional electrostatic chuck, a need has arisen to propose a novel electrostatic chuck that is capable of achieving workpiece temperatures lower than those possible with conventional electrostatic chucks that use heat transfer assemblies made of elastomeric materials and/or metal, and is capable of achieving higher cooling/heating rates than those possible with conventional electrostatic chucks.

### SUMMARY OF THE INVENTION

In view of the foregoing, the present invention provides a temperature-controllable electrostatic chuck capable of substantially decreasing and/or elevating the workpiece temperature without degrading some elements (e.g., tubes for circulating the heat-transfer fluid and mechanisms for translating/rotating the workpiece). The present invention also achieves required workpiece temperature with higher cooling or heating rate, and also achieves required workpiece temperature with precise temperature control.

According to one embodiment, a temperature-controllable electrostatic chuck capable of holding a workpiece includes a heat-transfer body, one or more electrodes and one or more thermopile devices. The heat-transfer body is disposed in a bottom portion of the electrostatic chuck and configured to transfer heat between the interior of the electrostatic chuck and the exterior of the electrostatic chuck via a heat-transfer assembly in which heat-transfer fluid is circulated between the heat-transfer body and a chiller external to the electrostatic chuck. The electrodes are disposed in the upper portion of the electrostatic chuck so that a workpiece may be clamped over the top surface of the electrostatic chuck. Each of the thermopile devices is disposed in the upper portion of the electrostatic chuck and configured to transfer heat between the heat-transfer body and the top surface wherein the thermopile devices are in series between the top surface and the heat-transfer assembly.

According to other embodiment, a semiconductor processing tool has at least an electrostatic chuck, a chiller, one or more power supplies and an actuator. The electrostatic chuck has a heat-transfer body disposed in a bottom portion of the electrostatic chuck and is configured to transfer heat between the interior of the electrostatic chuck and the exterior of the electrostatic chuck via a heat-transfer assembly. The electrostatic chuck also has one or more electrodes disposed in an upper portion of the electrostatic chuck, and one or more thermopile devices disposed in the upper portion of the electrostatic chuck and configured to transfer heat between the heat-transfer body and the top surface of the electrostatic chuck. The chiller is configured to transfer the heat via a heat-transfer assembly, such as a combination of an inward heat-transfer tube and an outward heat-transfer tube, with heat-transfer fluid circulated to and from the heat-transfer body. The power supplies are configured to drive the thermopile devices flexibly, and the actuator is configured to translate and/or rotate the electrostatic chuck.

### BRIEF DESCRIPTION OF THE DRAWINGS

FIG. 1 shows a schematic diagram illustrating a basic configuration of a conventional ion implanter;

FIG. 2 shows an exemplary beam path of scanning an ion beam with a beam cross-section on a conventional workpiece;

FIG. 3 schematically shows a conventional electrostatic chuck capable of holding a wafer;

FIG. 4 shows an exemplary response curve illustrating the relationship between workpiece temperature and elapsed time on a conventional electrostatic chuck operating at −50° C.;

FIG. 5 shows a schematic diagram of a temperature-controllable electrostatic chuck according to one embodiment of the present invention;

FIG. 6 shows a schematic diagram of the Peltier device driven by a power supply;

FIG. 7A shows an exemplary response curve illustrating the relationship between workpiece temperature and elapsed time according to one embodiment; and

FIG. 7B shows other exemplary response curve illustrating the relationship between workpiece temperature and elapsed time according to other embodiment.

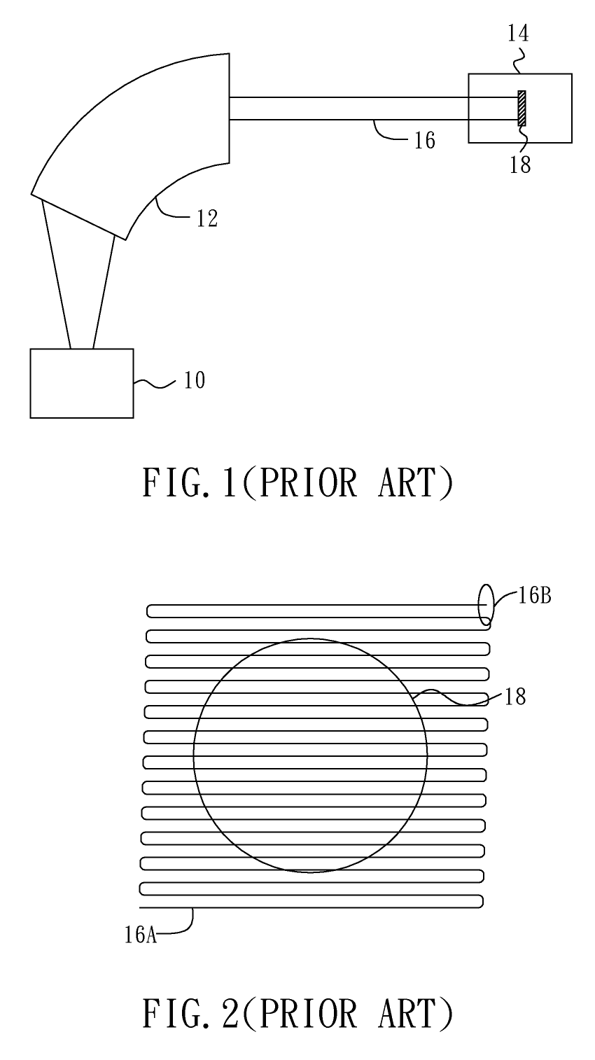

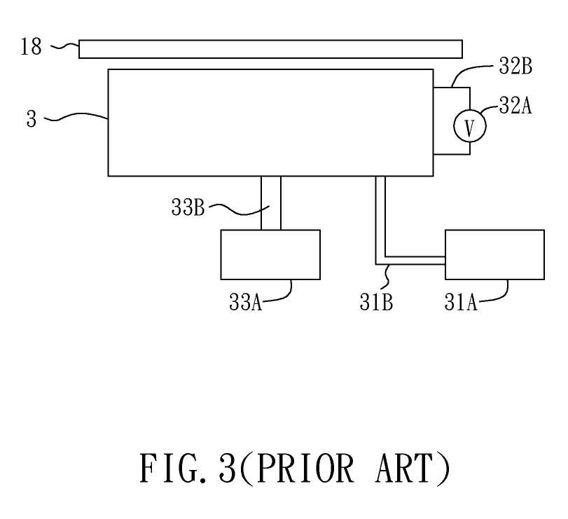

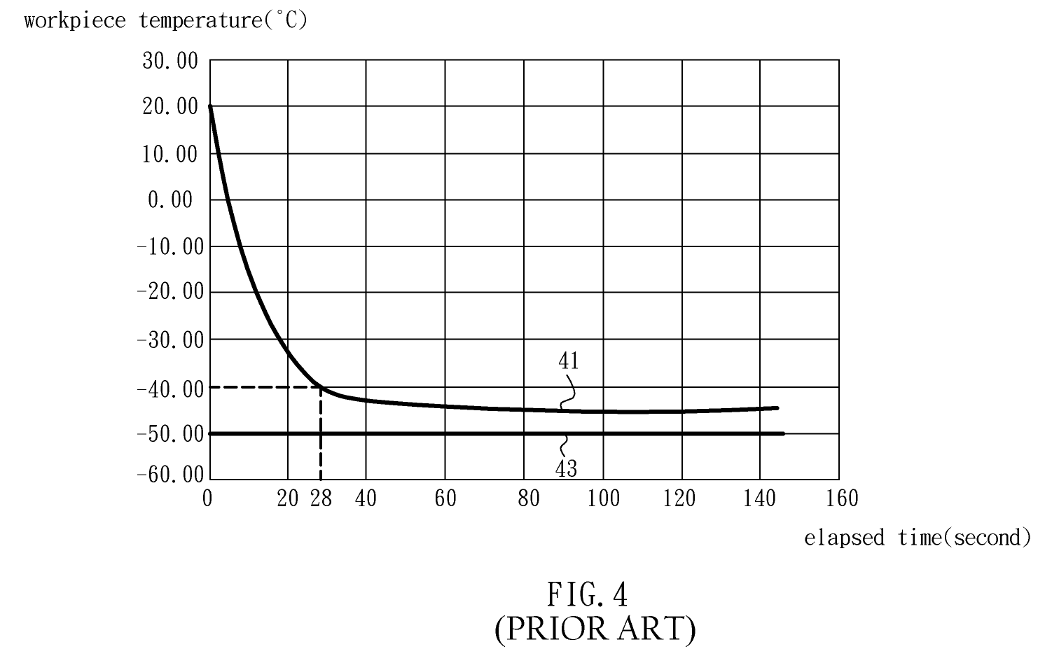

### DETAILED DESCRIPTION OF THE INVENTION

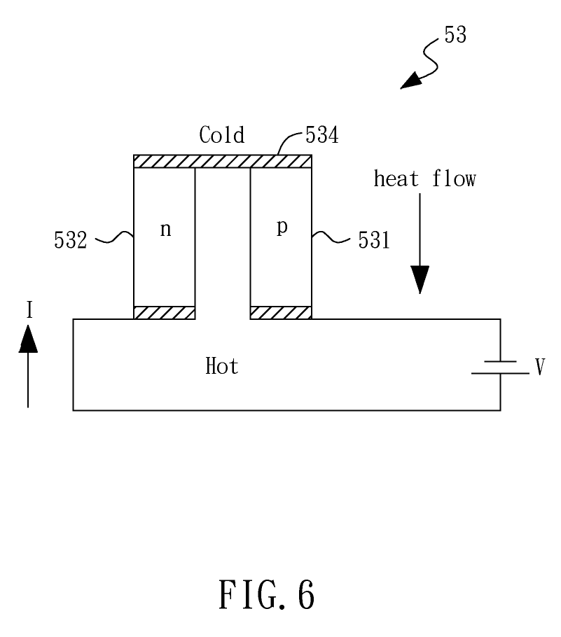

FIG. 5 shows a schematic diagram of a temperature-controllable electrostatic chuck 5 according to one embodiment of the present invention. The electrostatic chuck 5 is used for holding a workpiece 6 in at least a processing step. The workpiece 6 may be a wafer, a glass plate, a semiconductor plate or any plate-like object. It is appreciated by those skilled in the pertinent art that the present embodiment may be adaptable to many types of processing steps, such as ion implantation, doping, etching and so on.

The electrostatic chuck 5 is capable of lowering the temperature of the held workpiece 6 below, e.g., −90° C., without incurring degradation of materials (such as brittle failure of elastomeric or metal) of associated elements leading to the electrostatic chuck 5. As usual, a dielectric layer, which is used as a protective cover, may be formed on the upper portion of electrostatic chuck. Also, the workpiece may be held on one or more lift pins projected out from a top surface of the electrostatic chuck, these pins being used to lower the workpiece onto the chuck surface or raise the workpiece from the surface. Alternatively, the workpiece may be directly placed on the top surface of the electrostatic chuck by other means, such as an end effector. Because there are numerous various designs of the electrostatic chuck, these parts are not shown for the brevity of the figure.

Referring back to FIG. 5, the electrostatic chuck 5 includes one or more electrodes 51 connected, together or respectively, to one or more electric power supply (not shown again for the brevity of the figure), so that different electrodes 51 may be operated together or respectively. The electrostatic force generated by the electrodes 51 induce charges on the held workpiece 6, and then the workpiece 6 may be clamped onto the top surface 50A of the electrostatic chuck 5 (e.g., the workpiece 6 may be held and close to the upper portion 50 of the electrostatic chuck 5). In the embodiment, several electrodes 51 are horizontally disposed in the upper portion 50 of the electrostatic chuck 5. There are various commercial electrostatic chucks, hence, the electrodes 51 may be arranged and disposed in a manner other than that shown in FIG. 5.

In the embodiment, the electrostatic chuck 5 has one or more heat-transfer bodies 52A. Each heat-transfer body 52A is disposed in a bottom portion of the electrostatic chuck 5 and configured to transfer heat between the interior of the electrostatic chuck 5 and the exterior of the electrostatic chuck 5 via a heat-transfer assembly 52B, such as two tubes capable of inwardly and outwardly circuiting a heat-transfer fluid respectively, in which heat-transfer fluid is circulated between the heat-transfer body 52A and a chiller 52C external to the electrostatic chuck 5. The heat-transfer body(s) 52A, the heat-transfer assembly(s) 52B and the chiller(s) 52C together act as a heat sink mechanism. To allow the movement of the electrostatic chuck 5, the heat-transfer assembly 52B may be made of, but is not limited to, metal or elastomeric material such as plastic or rubber.

According to one aspect of the embodiment, the electrostatic chuck 5 includes one or more thermopile devices 53. In general, each thermopile device 53 is driven by an electric power (or an electric voltage) and is capable of generating a temperature differential between different sides (such as two opposite sides) of the thermopile device 53. Hence, when two structures are adjacent to different sides of the thermopile device 53 respectively, the heat may be pumped from one structure through the thermopile device 53 to the other structure. One popular commercial thermopile device 53 is the Peltier device, but the thermopile device 53 is not limited to be the Peltier device only. Different thermopile device 53 may generate different temperature differentials across different sides. For example, some current commercial thermopile devices 53 usually can generate a temperature differential of approximately 72° C. Moreover, because different thermopile device 53 may be driven by different electric powers respectively, several thermopile devices 53 may be combined in series to form a multistage device capable of achieving a greater temperature differentials which is not efficiently achieved by using one and only one thermopile device 53.

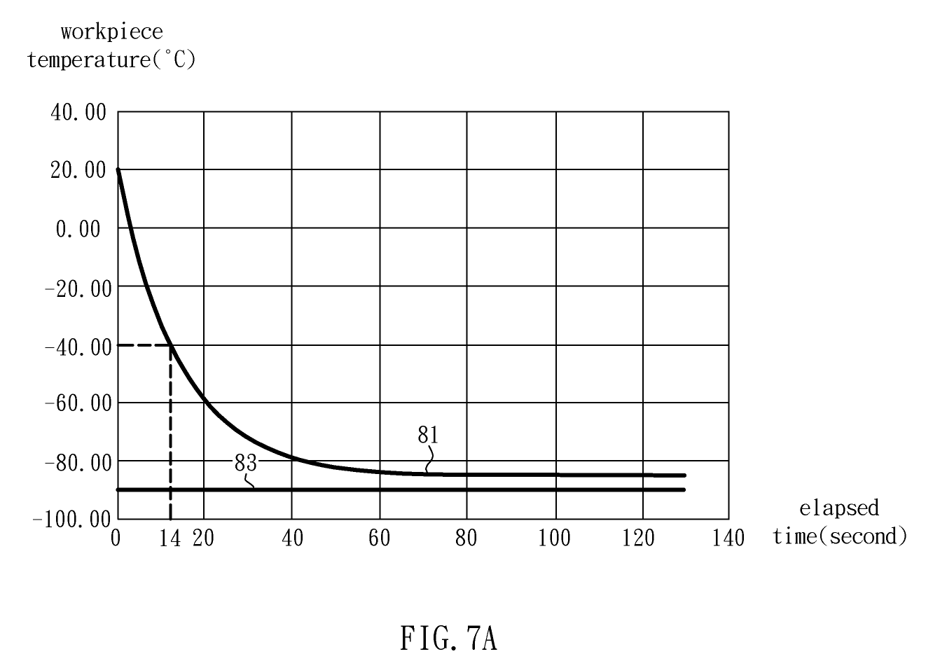

FIG. 6 shows a schematic diagram of a Peltier device 53 driven by a power supply V. The Peltier device 53 primarily includes a p-type semiconductor element 531 and an n-type semiconductor element 532 that are electrically connected in series via a metallic junction layer 534, i.e., the shown Peltier device 53 has a single stage structure. In different embodiments, the Peltier device 53 also may have a multiple stage structure with repeatedly arranged p-type semiconductor element 531, n-type semiconductor element 532, and metallic junction layer 534.

In the embodiment shown in FIG. 5, each thermopile device 53 is disposed in the upper portion of the electrostatic chuck 5, and is disposed in series between the heat-transfer body 52A and the top surface 50A upon which the workpiece 6 may be positioned. Specifically speaking, the cold side of the thermopile device 53 faces the top surface 50A, and the hot side of the thermopile device 53 faces the heat-transfer assembly 52A. Accordingly, the heat applied on the top surface 50A (such as the heat transferred from the workpiece 6 to the electrostatic chuck 5) can be transferred from the cold side of the thermopile device 53 to the hot side of the thermopile device 53, and then can be further carried away by the heat-transfer fluid in the heat-transfer body 52A. Thereby, the application of the thermopile device 53 substantially cools down the top surface 50A and any element positioned on the top surface 50A to a temperature substantially lower than that provided by the chiller 52C.

In addition, to ensure the workpiece 6 is tightly held and the workpiece 6 is properly processed, in one embodiment, the electrodes 51 disposed in the upper portion of the electrostatic chuck 5 are disposed between the top surface 50A and the thermopile device 53.

For example, if a −50° C. chiller 52C is used in series with a thermopile device 53 with 40° C. temperature differential, a temperature as low as −90° C. at the top surface 50A of the electrostatic chuck 5 may be achieved. Thus, the workpiece 6 held on the top surface 50A also may be cooled to about −90° C. it is worthy of noting that the thermopile device 53 is disposed in the upper portion of the electrostatic chuck 5 but relatively far away from other parts of the electrostatic chuck 5, such as the heat-transfer assembly 52B and any actuators used for moving the electrostatic chuck 5 (e.g., a motor 54 that controls translation and/or rotation of the electrostatic chuck 5).

As a result, while the upper portion of the electrostatic chuck 5 may be cooled to a very low temperature, the temperature at the lower portion of the electrostatic chuck 5 may be maintained at a temperature suitable to prevent failure of the connection materials (e.g., metal, plastics or rubbers). This is a significant benefit when the electrostatic chuck 5 is subjected to rotation and/or translation. In other words, all tubes and other flexible elements that are disposed in the lower portion of the electrostatic chuck 5 are operating within acceptable temperature limitations and will not incur low temperature failure during movements of the electrostatic chuck.

Furthermore, with the upper portion of the electrostatic chuck 5 being extremely cold, the workpiece 6 moved from an atmosphere environment at a room temperature into a chamber and then held on the electrostatic chuck 5 will have a higher cooling rate compared to a workpiece 18 under similar conditions except held on the conventional electrostatic chuck 3. The reason is simple, the larger the temperature differential, the greater the heat transfer rate.

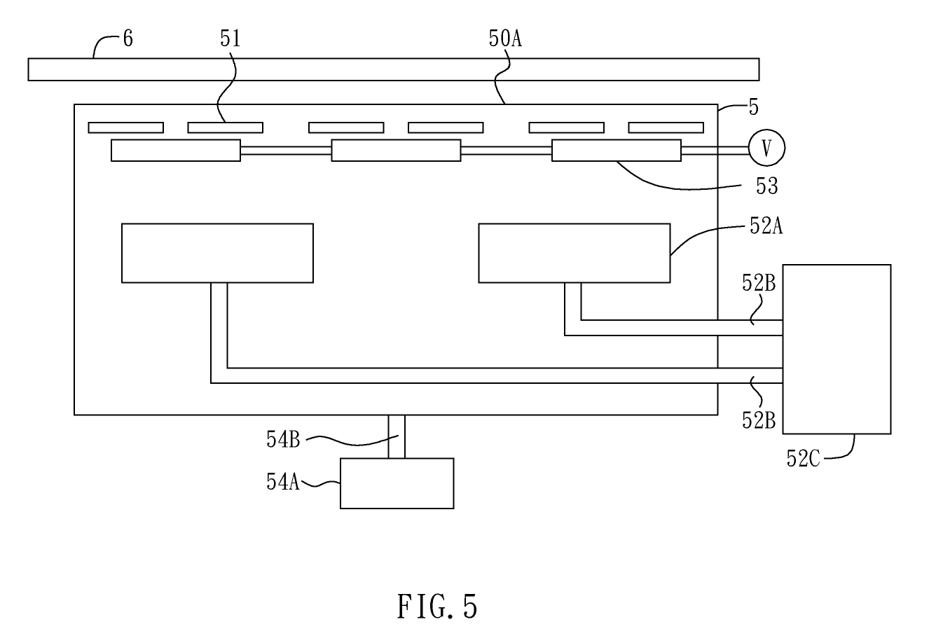

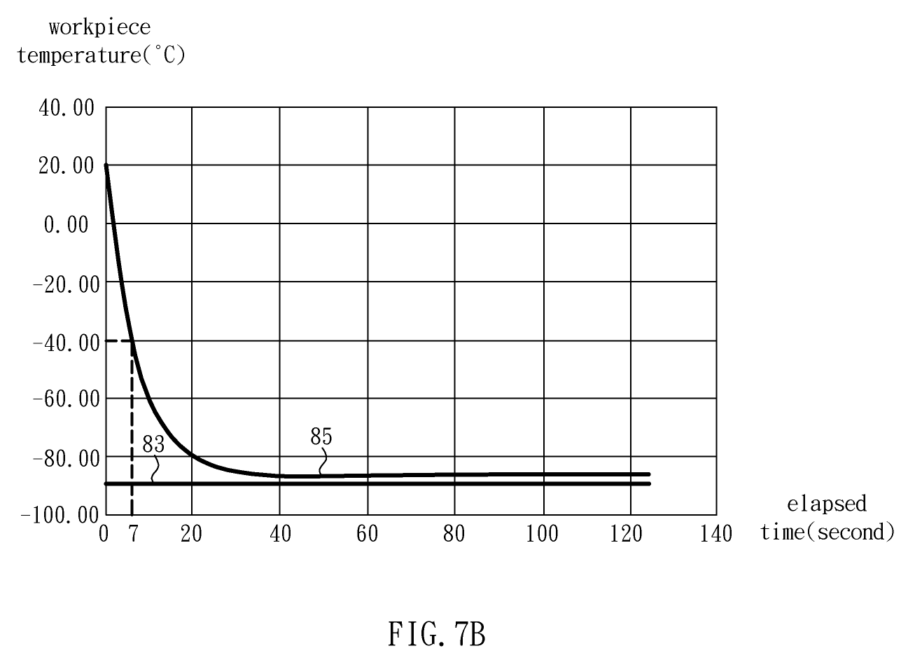

FIG. 7A shows an exemplary response curve illustrating the relationship between workpiece temperature 81 and elapsed time according to one embodiment. In this example, the workpiece 6 is held on the electrostatic chuck 5 and a gas exists between the held workpiece 6 and the electrostatic chuck 5 for use as a thermal medium. Hence, the heat may be efficiently transferred from the held workpiece 6 to the electrostatic chuck 5, even if the held workpiece 6 is not closely in contact with electrostatic chuck 5. To enhance the heat transfer efficiency, as a potential example, the upper portion of the electrostatic chuck 5 resembles a waffle, having a series of ridges and valleys, so that numerous small interstices are formed. The gas existing in these small interstices behaves as thermal medium between the upper portion and a workpiece held on the top surface. For example, the gas can get under about 30-70% of the workpiece 6 and the workpiece 6 is in contact with the remaining 70-30% of the top surface 50A. The pressure of the essentially static gas trapped in the waffle structure under the held workpiece 6 and above the top surface 50A of the electrostatic chuck 5 is at 10 Torr in this example. Also, both the thermopile device(s) 53 and the chiller(s) 52B at −50° C. in series with the thermopile device(s) 53 with a 40° C. temperature differential are used to cool the held workpiece 6. It is observed that the workpiece temperature takes about 14 seconds to get from 20° C. down to −90° C. The resultant cooling rate in this example is greater than that provided by the conventional electrostatic chuck (as shown in FIG. 4). FIG. 7B shows other exemplary response curve illustrating the relationship between workpiece temperature 85 and elapsed time according to other embodiment. In this example, the workpiece 6 is cooled when the gas pressure is at 20 Torr, when other parameters are adjusted to be the same as the example shown in FIG. 7A. It is observed that the workpiece temperature takes about 7 seconds to get down to 90° C. (from 20° C.); clearly, the cooling rate in this example is greater than that observed in FIG. 7A.

Note that the best gas pressure for best heat transferring rate through the gas is dependent on at least the practical configuration of electrostatic chuck 5, especially the configuration of the upper portion of the electrostatic chuck 5, and the practical configuration of the workpiece 6. Some experiments indicates that 10˜20 Torr is a suitable range, as the results in the previous examples, but the invention is not limited by the gas pressure. The use of gas pressure to control workpiece temperature is anticipated in view of the great cooling rates that can be achieved with a large temperature differential. For example, the gas pressure may be lowered or removed when the workpiece reaches the desired temperature even though that temperature is higher than the electrostatic chuck temperature. This pressure control in conjunction with modulation of the thermopile can control heat flow from the workpiece at the desired temperature as required by the process.

The practical advantages of higher cooling rate are significant. For example, when the workpiece 6 can be cooled quickly by the proposed electrostatic chuck 5, one or more pre-cooling steps may be omitted. For example, the workpiece 6 can be directly moved from the atmosphere environment to the proposed electrostatic chuck 5 located in a process chamber and then be directly cooled at the processing position where the workpiece is processed in the process chamber. In contrast, in the conventional skill, due to the slow cooling rate, one or more pre-cooling steps may be required before the workpiece being finally cooled down to the required temperature and being moved to the processing position.

Note that the operation of the thermopile device 53 only requires that one side of the thermopile device 53 faces a heat reservoir, and other side of the thermopile device 53 faces the target to be cooled. Hence, the configuration of the thermopile device 53 in the upper portion of the electrostatic chuck 5 may be flexibly adjusted, except that the thermopile devices 53 must be in series between the top surface 50A and the heat-transfer assembly 52B.

Besides, the thermal mass of the thermopile device 53 is significantly smaller than the thermal mass of other parts of the electrostatic chuck 5, also the size of the thermopile device 53 is relatively small. Thus, the electrostatic chuck 5 may still be compact after the thermopile device 53 being included. Moreover, the working voltage of the thermopile device 53 is small, thus, how the workpiece 6 is clamped by the electrodes 51 of the electrostatic chuck 5 is not degraded by the operation of the thermopile device 53.

Further, the operation of the electric power supply used to drive the thermopile device 53 may be turned on and off instantly, or continuously varied between a maximum value and a minimum value. Hence, the heat pump function provided by the thermopile device 53 may be switched between on and off immediately or be continuously varied within its capacity. Therefore, by flexibly selecting and maintaining the temperature differential across the thermopile device with the thermopile device's capability, the heat pumping rate may be servo controlled during the cooling/heating process to and precisely adjust the workpiece temperature. In other words, the temperature of the workpiece 6 may be flexibly and precisely adjusted, even if the operation of the chiller 52C is essentially fixed.

For example, when the workpiece 6 is at essentially a desired temperature after a cooling period, the thermopile device 53 may be turned off temporarily to avoid further cooling. Then, the workpiece 6 may be processed at essentially the desired temperature. However, the process may bring heat into the workpiece 6 so that the practical temperature of the workpiece 6 is increased during a processing period. Hence, when a differential between the practical workpiece temperature and the required workpiece temperature is larger than a predetermined value, the thermopile device 53 may be turned on immediately to cool down the workpiece 6 until the workpiece 6 is at essentially the desired temperature again.

For example, when the workpiece 6 is moved from an external chamber into a process chamber and held by the proposed temperature-controllable electrostatic chuck 5, the thermopile device(s) 53 may be operated initially with a maximum voltage to cool the workpiece 6 most quickly. Then, when the workpiece 6 is at about the desired temperature, the voltage may be continuously varied in conventional servo system type operation to maintain that workpiece temperature essentially equal to the desired temperature. In such situation, the voltage may be decreased to slowly cool the workpiece, even the voltage direction may be reversed to heat the workpiece if that is required to maintain the desired temperature.

Furthermore, besides the adjustment of the operation of the thermopile device(s) 53, the workpiece temperature may be adjusted by other practical means. For example, when the workpiece 6 reaches the desired temperature, the held workpiece 6 may be moved away from the thermopile device(s) 53 by using extendable lift pins or other equivalent mechanism. Hence, the operation of the thermopile device(s) 53 is not significantly adjusted and may even be fixed. For example, the thermopile device(s) 53 and the chiller 52C may be set at their maximum lowest temperature, so that the held workpiece 6 may be cooled to a desired temperature most quickly. When the desired temperature is achieved, the workpiece 6 may be lifted away from the thermopile device(s) 53 to avoid further cooling. In this case, the desired temperature is not the same as the available lowest temperature. Clearly, this way is more suitable for both pre-cooling activity and pre-heating activity, because the workpiece usually is tightly held again the support assembly in a process chamber to transfer heat and maintain control of workpiece while the workpiece is manipulated.

In short, with the usage of the thermopile device 53, not only the temperature of the workpiece 6 located close to the proposed electrostatic chuck 5 may be extended, but also the control of the temperature of the workpiece 6 may be improved. Note that the thermopile device 53 is well-known to persons skilled in the pertinent art and has been used in the fabrication of integrated circuits. Therefore, when the invention proposes new applications of the thermopile device 53, such as extending available workpiece temperature range and improving workpiece temperature control capabilities, details of the thermopile device(s) 53, such as the composition and the construction, are omitted for brevity.

In at least some of the above embodiments, the thermopile device 53 is used to cool the workpiece 6. However, in other embodiments, the thermopile device 53 may be used for heating instead. The heating step can be performed simply by reversing the orientation of the thermopile device 53. That is, the hot side of the thermopile device 53 faces the workpiece 6, and the cold side of the thermopile device 53 faces the heat-transfer body 52A. Specifically, heat is transferred from the heat-transfer body 52A to the cold side of the thermopile device 53, and then is further transferred to the hot side of the thermopile device 53. Therefore, due to the temperature differential across the thermopile device 53, the workpiece 6 close to the top surface 50 A is substantially heated up to a substantially higher temperature. For example, if a chiller 52C at 100° C. is used in series with a thermopile device 53 with a 60° C. temperature differential, the workpiece temperature may be as high as 160° C. Note that the temperature at the lower portion of the electrostatic chuck 5 may be maintained at a proper temperature, e.g., 100° C., while the high temperature, e.g., 160° C., may be achieved only at the upper portion of the electrostatic chuck 5.

In a further embodiment, the commonly used nitrogen gas (which may be used as a cleaning gas during a cleaning process or a back side gas for carrying heat away from an implanted workpiece during an implanting process) is applied to the space between the workpiece 6 and electrostatic chuck 5 for improving the heat-transfer efficiency. However, the invention does not limit the kind of the gas, the pressure range, or how the gas is disposed in the space. Indeed, any conventional skill capable of distributing gas under the workpiece may be used to ensure the existence of the gas.

The proposed electrostatic chuck may be applied in many semiconductor processing tools in which a workpiece is held, even translated/rotated, during a processing period. For example, the proposed electrostatic chuck may be applied in the ion implanter, or any processing tool having the plasma chamber. Except the electrostatic chuck having one or more heat-transfer bodies, one or more thermopile devices and one or more electrodes as discussed above, the semiconductor processing tool may have a heat-transfer assembly configured to transfer heat via heat-transfer fluid circulated between the heat-transfer body and a chiller, and one or more power supplies for driving the thermopile device(s) and the electrode(s). Moreover, when the workpiece is not static during the processing period, the semiconductor processing tool may have an actuator configured to move the electrostatic chuck with respect to an ion beam so that the distribution of processing result over the workpiece is more adjustable. For example, to translate the electrostatic chuck in any direction, to rotate the electrostatic chuck about any axis, even to twist the electrostatic chuck about any axis. In addition, when the semiconductor processing tool is an ion implanter, it may further have an ion source capable of generating an ion beam, and a mass analyzer capable of filtering ions without desired charge-to-mass ratio out the ion beam before the workpiece held being implanted by the ion beam.

Although specific embodiments have been illustrated and described, it will be appreciated by those skilled in the art that various modifications may be made without departing from the scope of the present invention, which is intended to be limited solely by the appended claims.

What is claimed is:

1. A temperature-controllable electrostatic chuck, comprising:
a heat-transfer body disposed in a bottom portion of the electrostatic chuck and configured to transfer heat between the interior of the electrostatic chuck and the exterior of the electrostatic chuck via a heat-transfer assembly in which heat-transfer fluid is circulated between the heat-transfer body and a chiller external to the electrostatic chuck;
one or more electrodes disposed in an upper portion of the electrostatic chuck; and
one or more thermopile devices disposed in the upper portion of the electrostatic chuck and configured to transfer heat between the heat-transfer body and a top surface of the electrostatic chuck.

2. The electrostatic chuck of claim 1, wherein the electrodes are disposed between the top surface and the thermopile devices.

3. The electrostatic chuck of claim 1, wherein each of the electrodes is connected to an electric power supply and capable of generating an electrostatic force for clamping a workpiece on the top surface.

4. The electrostatic chuck of claim 1, wherein the thermopile devices are in series between the top surface and the heat-transfer assembly.

5. The electrostatic chuck of claim 1, wherein each of the thermopile devices is driven by an electric power and capable of generating a temperature differential between two different sides of the thermopile device.

6. The electrostatic chuck of claim 1, wherein a cold side of the thermopile device faces the top surface and a hot side of the thermopile device faces the heat-transfer body, whereby a workpiece held on the top surface can be cooled.

7. The electrostatic chuck of claim 1, wherein a hot side of the thermopile device faces the top surface and a cold side of the thermopile device faces the heat-transfer body, whereby a workpiece held on the top surface can be heated.

8. The electrostatic chuck of claim 1, wherein one of the thermopile devices is a Peltier device, which includes one p-type semiconductor element and one n-type semiconductor element connected in series via a metallic junction layer, wherein the p-type semiconductor element and the n-type semiconductor element are driven by a power supply.

9. The electrostatic chuck of claim 1, wherein the upper portion resembles a waffle having series of ridges and valleys so that a plurality of small interstices are formed, whereby gas exists in the small interstices behaves as thermal medium between the upper portion and a workpiece held on the top surface.

10. The electrostatic chuck of claim 1, wherein the material of the heat-transfer assembly is chosen from a group consisting of the following: plastic, rubber, metal and any combination thereof.

11. A semiconductor processing tool, comprising:
an electrostatic chuck, the electrostatic chuck comprising:
a heat-transfer body disposed in a bottom portion of the electrostatic chuck and configured to transfer heat between the interior of the electrostatic chuck and the exterior of the electrostatic chuck;
one or more electrodes disposed in an upper portion of the electrostatic chuck; and
one or more thermopile devices disposed in the upper portion of the electrostatic chuck and configured to transfer heat between the heat-transfer body and a top surface of the electrostatic chuck;
a heat-transfer assembly configured to transfer heat via heat-transfer fluid circulated between the heat-transfer body and a chiller;
one or more power supplies configured to drive the thermopile devices; and
an actuator configured to move the electrostatic chuck.

12. The processing tool of claim 11, wherein each of the electrodes is disposed between the top surface and the thermopile devices, also connected to an electric power supply and capable of generating an electrostatic force for clamping a workpiece on the top surface.

13. The processing tool of claim 11, wherein the thermopile devices are in series between the top surface and the heat-transfer assembly.

14. The processing tool of claim 11, wherein a cold side of the thermopile device faces the top surface and a hot side of the thermopile device faces the heat-transfer body, whereby a workpiece held on the top surface can be cooled.

15. The processing tool of claim 11, wherein a hot side of the thermopile device faces the top surface and a cold side of the thermopile device faces the heat-transfer body, whereby a workpiece held on the top surface can be heated.

16. The processing tool of claim 11, wherein one of the thermopile devices is a Peltier device, which includes one p-type semiconductor element and one n-type semiconductor element connected in series via a metallic junction layer, wherein the p-type semiconductor element and the n-type semiconductor element are driven by a power supply.

17. The processing tool of claim 11, wherein the upper portion resembles a waffle having series of ridges and valleys so that a plurality of small interstices are formed, whereby gas exists in the small interstices behaves as thermal medium between the upper portion and a workpiece held on the top surface.

18. The processing tool of claim 11, wherein the material of the heat-transfer assembly is chosen from a group consisting of the following: plastic, rubber, metal and any combination thereof.

19. The processing tool of claim 11, wherein the actuator is capable of performing one or more of the following:
translating the electrostatic chuck in any direction;
rotating the electrostatic chuck about any axis; and
tilting the electrostatic chuck about any axis.

20. The processing tool of claim 11, further comprising:
an ion source capable of generating an ion beam; and
a mass analyzer capable of filtering ions without desired charge-to-mass ratio out the ion beam before the workpiece being implanted by the ion beam.
